(19) United States
(12) Patent Application Publication
(10) Pub. No.: US 2025/0337221 A1
(43) Pub. Date: Oct. 30, 2025

(54) INDEPENDENT CONTROL OF A POLARIZATION ORIENTATION AND AN OPTICAL MODE OF A VERTICAL-CAVITY SURFACE-EMITTING LASER

(71) Applicant: Lumentum Operations LLC, San Jose, CA (US)

(72) Inventors: Richa DUBEY, Milpitas, CA (US); Matthew Glenn PETERS, Menlo Park, CA (US)

(21) Appl. No.: 18/795,578

(22) Filed: Aug. 6, 2024

Related U.S. Application Data
(60) Provisional application No. 63/638,606, filed on Apr. 25, 2024.

(51) Int. Cl. H01S 5/183; H01S 5/42

(52) U.S. Cl. CPC H01S 5/18386; H01S 5/423

(57) ABSTRACT

In some implementations, a VCSEL includes a first cap layer and a second cap layer. The first cap layer includes a semiconductor material and is disposed over a confinement aperture of the VCSEL. The second cap layer includes a dielectric material and is disposed over the confinement aperture of the VCSEL. A polarization filter structure is formed in the first cap layer. A mode filter structure is formed in the second cap layer.

### CROSS-REFERENCE TO RELATED APPLICATION

This Patent Application claims priority to U.S. Patent Application No. 63/638,606, filed on Apr. 25, 2024, and entitled “SINGLE MODE AND SINGLE POLARIZED VERTICAL-CAVITY SURFACE-EMITTING LASERS.” The disclosure of the prior Application is considered part of and is incorporated by reference into this Patent Application.

### TECHNICAL FIELD

The present disclosure relates generally to a vertical-cavity surface-emitting laser (VCSEL) and to independent control of a polarization orientation and an optical mode of the VCSEL.

### BACKGROUND

An emitter can include a vertical-emitting device, such as a VCSEL. A VCSEL is a laser in which a laser beam is emitted in a direction perpendicular to a surface of the VCSEL (e.g., vertically from a surface of the VCSEL). Multiple emitters may be arranged in an emitter array with a common substrate.

### SUMMARY

In some implementations, a VCSEL includes a first cap layer including a semiconductor material disposed over a confinement aperture of the VCSEL; and a second cap layer including a dielectric material disposed over the confinement aperture of the VCSEL, wherein: a polarization filter structure is formed in the first cap layer, and a mode filter structure is formed in the second cap layer.

In some implementations, an optical assembly includes a plurality of VCSELs, wherein each VCSEL comprises: a first cap layer; and a second cap layer, wherein: a polarization filter structure is formed in the first cap layer, and a mode filter structure is formed in the second cap layer.

In some implementations, a wafer includes a plurality of VCSELs, wherein each VCSEL comprises: a polarization filter structure disposed over a confinement aperture of the VCSEL; and a mode filter structure disposed over the confinement aperture of the VCSEL.

### BRIEF DESCRIPTION OF THE DRAWINGS

FIGS. 1A-1B are diagrams associated with example implementations of a VCSEL.

FIG. 2 is diagram associated with an example optical device.

FIG. 3 is diagram associated with an example wafer.

FIGS. 4A-4B show single mode operation of similarly configured VCSELs.

### DETAILED DESCRIPTION

The following detailed description of example implementations refers to the accompanying drawings. The same reference numbers in different drawings may identify the same or similar elements.

VCSELs typically include two distributed Bragg reflector (DBR) mirrors arranged parallel to a wafer surface with an active region arranged between the two DBR mirrors. The active region includes one or more quantum wells for laser light generation. VCSELs are widely used in various applications, such as data communications, sensing, and optical interconnects, due to advantages over other types of lasers. For example, VCSELs typically have lower power consumption (e.g., VCSELs require much lower power to operate than other types of lasers, making them more energy-efficient and cost-effective), are capable of high-speed operation (e.g., making VCSELs ideal for data communications and other applications that require fast signal transmission), have narrow beam divergence (e.g., the narrow beam divergence of VCSELs allows for high coupling efficiency with optical fibers and other components, making VCSELs easier to integrate into optical systems), and have high reliability (e.g., VCSELs have a long operating lifetime and are less prone to failure than other types of lasers).

VCSELs can have a cylindrical symmetry and therefore have no preferred polarization orientation. Often, this results in VCSELs supporting a combination of modes lasing in different polarization orientations. However, VCSELs lasing in different polarization orientations is not desirable for many applications, such as data communication, optical systems requiring polarization sensitive optics, spectroscopy, and three-dimensional (3D) sensing, among other examples. For example, when individual VCSELs lase with different polarization orientations, the individual VCSELs can perform differently in the same application. Another problem is that a polarization orientation of a VCSEL can spontaneously change based on a condition of the VCSEL, such an ambient temperature, a current level, or a packaging stress, which makes a performance of the VCSEL unpredictable. For data communication, polarization hopping under different modulation conditions can cause high bit-error-rates (BERs), such as for polarization sensitive optical links.

Further, because of large lateral cavity dimensions or confinement apertures, VCSELs often demonstrate spatial multi-modal behavior. The higher the number of modes that are supported by a VCSEL, the more unstable a polarization state of each mode becomes. In some cases, single mode operation in VCSELs can be achieved by using smaller confinement apertures. However, this often results in lower power and decreased reliability of the VCSELs. Manufacturability of such small confinement apertures is also difficult.

Some implementations described herein include a VCSEL. The VCSEL includes a first cap layer and a second cap layer that are both disposed (e.g., in a stack) over a confinement aperture of the VCSEL. The first cap layer includes a polarization filter structure (e.g., that comprises gratings), which is configured to support a single polarization orientation of a laser beam emitted by the VCSEL. The second cap layer includes a mode filter structure, which is configured to support a reduced number of optical modes (e.g., a reduced number of spatial optical modes), such as a single optical mode (e.g., a single spatial optical mode), of the laser beam.

In this way, the VCSEL provides a consistent quantity of optical modes and a single polarization orientation for each optical mode. For example, the VCSEL can support a single mode and a single polarization orientation. This can facilitate a low relative intensity noise (RIN) of the VCSEL and an improved light-current (LI) performance of the VCSEL (e.g., in terms of a kink behavior in LI curves associated with the VCSEL). Further, some implementations described herein enable VCSEL performance uniformity, without impacting a power and reliability of the VCSEL (e.g., as compared to reducing a size of the confinement aperture).

Accordingly, the VCSEL described herein, in at least some cases, is a preferred VCSEL for data communication, optical systems requiring polarization sensitive optics, spectroscopy, and 3D sensing, among other examples. For example, many of the VCSELs described herein can be configured to lase with a same polarization orientation and therefore perform consistently in the same application. Further, a performance of the VCSELs are consistent even under varying or different conditions of the VCSELs. This therefore can reduce BERs, such as for polarization sensitive optical links associated with data communications.

Notably, the polarization filter structure and the mode filter structure described herein are formed in different layers of the VCSEL. Accordingly, each can be formed to have optimal characteristics. For example, characteristics of the polarization filter structure (e.g., an etch depth of the polarization filter structure, a pitch of gratings of the polarization filter structure, a pattern of the gratings of the polarization filter structure, a shape of the polarization filter structure, a direction of grooves of the polarization filter structure, and/or a size of the polarization filter structure) may suppress support of more than one polarization orientation by the polarization filter structure. As another example, characteristics of the mode filter structure (e.g., an etch depth of the mode filter structure, a size of the mode filter structure, and/or a shape of the mode filter structure 126) may reduce a quantity of optical modes supported by the mode filter structure. Notably, by being formed in respective cap layers, the polarization filter structure and the mode filter structure can be independently designed (or independently selected). That is, the VCSEL can provide independent control of a polarization orientation and an optical mode of the VCSEL.

In this way, both filter structures can be designed to provide an optimal performance (e.g., an optimal optical mode performance and an optimal polarization orientation performance), which cannot be otherwise accomplished. For example, a conventional VCSEL can use a same layer or structure to attempt to control a quantity of modes and polarization orientation, but the physical dimensions of the layer or structure cannot be optimal for both optical mode control and polarization orientation control (e.g., because it is limited to a single etch depth).

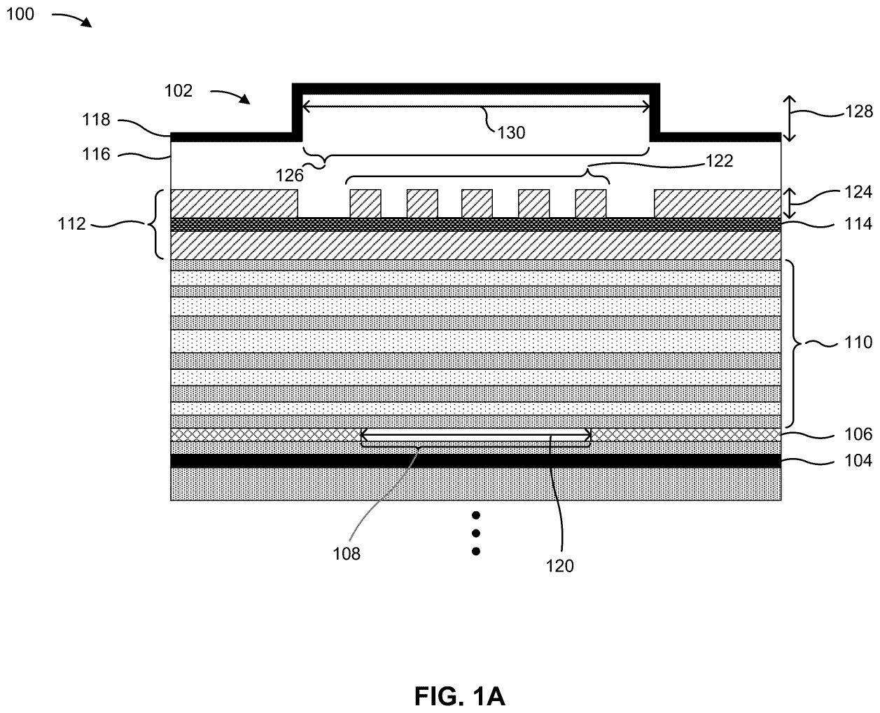

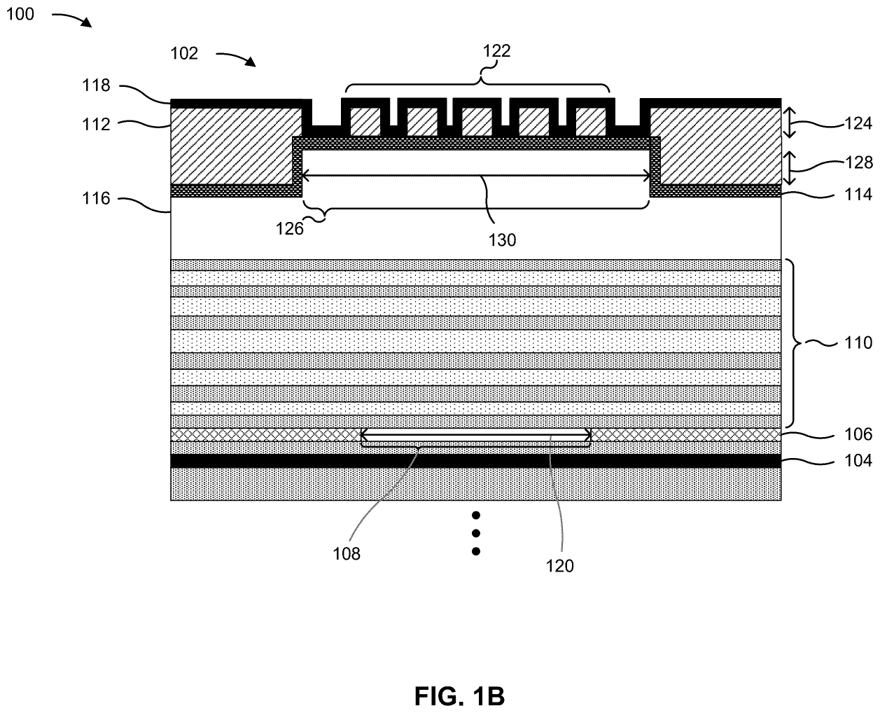

FIGS. 1A-1B are diagrams associated with example implementations 100 of a VCSEL 102. In some implementations, the VCSEL 102 may be included in an array of emitters (e.g., an array of VCSELs 102). In some implementations, as illustrated in FIGS. 1A-1B, the VCSEL 102 is a top-emitting emitter. Alternatively, the VCSEL 102 may in some implementations be a bottom-emitting emitter (e.g., with a similar structure to that shown in FIGS. 1A-1B, with modifications to enable bottom-emitting). As shown in FIGS. 1A-1B, the VCSEL 102 may include a cavity including one or more active regions (herein referred to as cavity region 104), a confinement layer 106 that forms a confinement aperture 108, a mirror structure 110, a first cap layer 112, an etch stop layer 114, a second cap layer 116, and/or a protective layer 118. The cavity region 104, the confinement layer 106, the mirror structure 110, the first cap layer 112, the etch stop layer 114, the second cap layer 116, and the protective layer 118 may be formed over a substrate, an additional mirror structure, and/or one or more other layers and/or structures (not shown in FIGS. 1A-1B to facilitate clarity and ease of explanation).

Cavity region 104 includes one or more layers where electrons and holes recombine to emit light and define the emission wavelength range of the VCSEL 102. For example, the cavity region 104 may include one or more active regions in the form of one or more quantum wells (QWs). In some implementations, the cavity region 104 may include one or more cavity spacer layers (e.g., to enable epitaxial growth to have sufficient room for ramping compositions or temperature). In some implementations, the one or more cavity spacer layers may reduce strain between active regions of the cavity region 104 and/or may mitigate thermal issues of laser operation of the VCSEL 102. In some implementations, the one or more cavity spacer layers may include an oxidation layer. In some implementations, the cavity region 104 includes a set of layers grown using a metal-organic chemical vapor deposition (MOCVD) technique, a molecular beam epitaxy (MBE) technique, or another technique. In some implementations, a plurality of cavity regions 104 may be included within the VCSEL structure.

An optical thickness of the cavity region 104 (including the one or more active regions and any cavity spacer layers), the confinement layer 106, the mirror structure 110, the first cap layer 112, the etch stop layer 114, and/or the second cap layer 116 (as well as any additional layer or structure that the cavity region 104 is formed over, such as a substrate and another mirror structure) may define a resonant cavity wavelength of the VCSEL 102, which may be designed within an emission wavelength range of the cavity region 104 to enable lasing. The wavelength range of the VCSEL 102 may in some implementations be in a range from approximately 940 nanometers (nm) to approximately 1380 nm.

Confinement layer 106 is a layer that provides optical and/or electrical confinement for the VCSEL 102. In some implementations, the confinement layer 106 enhances carrier and mode confinement of the VCSEL 102 and, therefore, can improve performance of the VCSEL 102. In some implementations, the confinement layer 106 is on, under, or in the cavity region 104. In some implementations, there may be one or more spacer layers or mirror layers (e.g., one or more DBRs) between the confinement layer 106 and the cavity region 104. In some implementations, as shown in FIGS. 1A-1B, the confinement layer 106 is over the cavity region 104 such that the confinement layer 106 is on a side of the cavity region 104 nearer to the mirror structure 110 (i.e., on a non-substrate side of the cavity region 104).

In some implementations, the confinement layer 106 comprises, at least in part, an oxide layer formed by oxidation of one or more epitaxial layers of the VCSEL 102. For example, the confinement layer 106 may be an aluminum oxide (Al₂O₃) layer formed as a result of oxidation of an epitaxial layer (e.g., an AlGaAs layer, an AlAs layer, and/or the like). In some implementations, the confinement layer 106 may have a thickness in a range from approximately 0.007 micrometers (μm) to approximately 0.04 μm, such as 0.02 μm. In some implementations, in addition to the confinement layer 106, the VCSEL 102 may include one or more other types of structures or layers that provide current confinement, such as an implant passivation structure, a mesa isolation structure, a moat trench isolation structure, a buried tunnel junction, or the like. Additionally, or alternatively, other types of structures or layers for providing current confinement may be included in or integrated with the confinement layer 106.

In some implementations, the confinement layer 106 defines the confinement aperture 108. Thus, in some implementations, the confinement aperture 108 is an optically active aperture defined by the confinement layer 106. In some implementations, a size 120 (e.g., a width in a given direction) of the confinement aperture 108 is in a range from approximately 1 μm to approximately 300 μm, such as 5 μm or 8 μm. In some implementations, as described above, the confinement aperture 108 may be formed by oxidation (e.g., when the confinement layer 106 includes an oxidized layer), and thus the confinement aperture 108 may be referred to as an oxide aperture. Additionally, or alternatively, the confinement aperture 108 may be formed by other means, such as by implantation, diffusion, regrowth (e.g., using a high resistance layer, a current blocking layer, a tunnel junction, or the like), or an air gap, among other examples.

Mirror structure 110 is a reflector (e.g., a top reflector) of the optical resonator of the VCSEL 102. For example, the mirror structure 110 may include a plurality of DBR pairs, or another type of mirror structure. In some implementations, the mirror structure 110 is formed from a p-type material. Thus, in some implementations, the mirror structure 110 comprises a plurality of p-type DBR pairs. Alternatively, the mirror structure 110 may in some implementations be formed from an n-type material. In some implementations, the mirror structure 110 may have a thickness in a range from approximately 1 μm to approximately 6 μm, such as 3 μm. In some implementations, the mirror structure 110 includes a set of layers (e.g., AlGaAs layers) grown using an MOCVD technique, an MBE technique, or another technique. In some implementations, the mirror structure 110 is grown on or over the cavity region 104.

In some implementations, the first cap layer 112 may include a polarization filter structure 122 (e.g., formed in the first cap layer 112). The polarization filter structure 122 may include, for example, a grating structure (e.g., that includes one-dimensional gratings, or one or more other types of gratings). The polarization filter structure 122 may be disposed within the first cap layer 112 (e.g., fully disposed, such that no portion of the polarization filter structure 122 extends beyond the first cap layer 112). The polarization filter structure 122 may be associated with polarization of output light (e.g., a laser beam) emitted by the VCSEL 102. For example, the polarization filter structure 122 may introduce a polarization dependence to reflectivity and/or transmissivity of the VCSEL 102, an effect of which is suppression of one of the two orthogonal polarization orientations of the light (e.g., such that the light emitted by the VCSEL 102 has a single polarization orientation).

The polarization filter structure 122 (e.g., when the polarization filter structure 122 includes a grating structure) may generate anisotropic reflectivity or, in other words, different reflectivity for the transverse electric (TE) and transverse magnetic (TM) polarizations. The state of polarization with the lower reflectivity becomes comparatively more lossy and requires a higher threshold current. Eventually, the state of the polarization with the lower reflectivity either does not enter a stimulated emission regime at an operating current or lases near threshold with low power. The higher the power difference between the two polarization states, the stronger the polarization selectivity (i.e., the larger the polarization extinction ratio (PER)). Since reflectivity is altered by the presence of the polarization filter structure 122, penalties on performance can be expected. In some implementations, the polarization filter structure 122 of the VCSEL 102 can be designed using a rigorous coupled-wave analysis method so as to be optimized to minimize penalties on performance (e.g., threshold current or slope efficiency). In some implementations, the polarization filter structure 122 reduces or eliminates polarization switching in the VCSEL 102 by achieving a single dominating polarization state. As further described herein, in some implementations, the use of the etch stop layer 114 to control a depth of the polarization filter structure 122 enables the single dominating polarization state to be achieved in the VCSEL 102 (e.g., the polarization filter structure 122 may support a single polarization orientation). This may cause the VCSEL 102 to support a single polarization orientation. In some implementations, the polarization filter structure 122 may also be associated with increasing reflectivity on a side of the VCSEL 102 that includes the mirror structure 110.

In some implementations, the polarization filter structure 122 can be formed by etching of the first cap layer 112. In some implementations, the polarization filter structure 122 has a first etch depth 124, and a pitch (or period), that are on an order of or lower than a wavelength of the VCSEL 102. In some implementations, the polarization filter structure 122, such as when the polarization filter structure 122 includes a grating structure, may have a periodic pattern or an aperiodic pattern. Additionally, or alternatively, the grating structure of the polarization filter structure 122 may have a variety of shapes, such as a rectangular shape, a square shape, a triangular shape, a sinusoidal shape, among other examples, depending on a need in a given application. In some implementations, the polarization filter structure 122 can be formed using photolithography technique, deep ultraviolet (UV) lithography, nano-imprint lithography, or e-beam lithography, among other examples. In some implementations, the polarization filter structure 122 has a sub-wavelength scale feature size. In some implementations, as determined by design (e.g., grating design), the polarization that is provided by the polarization filter structure 122 can be in a direction parallel to grooves of the polarization filter structure 122 or can be in a direction perpendicular to the grooves of the polarization filter structure 122. Notably, the polarization filter structure 122 can be used for any shape of confinement aperture 108, such as a circular confinement aperture 108 or an asymmetric confinement aperture 108. Further, the polarization filter structure 122 can in some implementations fully cover the VCSEL 102. Alternatively, a shape of the polarization filter structure 122 (e.g., a shape of a border of the polarization filter structure 122, of a perimeter of the polarization filter structure 122, or of another similar characteristic of the polarization filter structure 122) may in some implementations match a shape of the confinement aperture 108. In some implementations, the polarization filter structure 122 may have a same or similar size as the size 120 of the confinement aperture 108. Alternatively, an overlap (within a tolerance) or a slightly larger polarization filter structure 122 than confinement aperture 108 may be used.

In some implementations, the first cap layer 112 is on, under, or in at least one of the mirror structure 110, the second cap layer 116, the protective layer 118, or any other layer or structure over (i.e., above, as shown in FIGS. 1A-1B) the confinement aperture 108. Accordingly, the polarization filter structure 122 may be on, under, or in at least one of the mirror structure 110, the second cap layer 116, the protective layer 118, or any other layer or structure over (i.e., above, as shown in FIGS. 1A-1B) the confinement aperture 108.

The etch stop layer 114 is a layer associated with controlling one or more parameters of the polarization filter structure 122 during etching of the polarization filter structure 122. That is, the etch stop layer 114 is a layer associated with controlling etching of the first cap layer 112 during formation of the polarization filter structure 122 in the first cap layer 112. In some implementations, the etch stop layer 114 is incorporated in the mirror structure 110 of the VCSEL 102. In some implementations, the etch stop layer 114 is incorporated in the first cap layer 112, as shown in FIG. 1A. In some implementations, the first cap layer 112 is disposed on the etch stop layer 114, as shown in FIG. 1B.

The first cap layer 112 may comprise a semiconductor material, such as GaAs and/or AlGaAs. In some implementations, a thickness of the first cap layer 112 may be in a range from approximately 0.2 μm to approximately 0.5 μm, such as 0.3 μm. In some implementations, the etch stop layer 114 comprises a material with a high etch selectivity with respect to the first cap layer 112. For example, the etch stop layer 114 may comprise a material with an etch selectivity that is greater than 10 (i.e., the first cap layer 112 etches 10 times faster than the etch stop layer 114). In some implementations, the etch stop layer 114 may comprise a material that has an etch selectivity of at least 100. In some implementations, the etch stop layer 114 may comprise indium gallium phosphide (InGaP) (e.g., when a substrate of the VCSEL 102 comprises GaAs). In some implementations, a thickness of the etch stop layer 114 is in a range from approximately 10 nanometers (nm) to approximately 100 nm, such as 20 nm.

The second cap layer 116 may comprise, for example, a dielectric material, such as silicon nitride (SiN_{X}), silicon dioxide (SiO₂), a polymer dielectric, or another type of insulating material. In some implementations, the second cap layer 116 has a thickness that is approximately equal to a multiple of (λ/2)×n, where λ is a design wavelength of the VCSEL 102 and n is a refractive index of a material of the second cap layer 116.

When the second cap layer 116 is disposed over the first cap layer 112 (e.g., as shown in FIG. 1A), the first cap layer 112 and the second cap layer 116 may comprise a semiconductor material and a dielectric material, respectively, as described herein. Alternatively, when the first cap layer 112 is disposed over the second cap layer 116 (e.g., as shown in FIG. 1B) the first cap layer 112 and the second cap layer 116 may comprise a dielectric material and a semiconductor material, respectively.

In some implementations, the second cap layer 116 may include a mode filter structure 126 (e.g., formed in the second cap layer 116). The mode filter structure 126 may include, for example, a stepped structure (e.g., with at least a bottom step and a top step). The mode filter structure 126 may be disposed within the second cap layer 116 (e.g., fully disposed, such that no portion of the mode filter structure 126 extends beyond the second cap layer 116). Additionally, or alternatively, the mode filter structure 126 (e.g., the top step of the stepped structure) may have a variety of shapes, such as a rectangular shape, a square shape, a triangular shape, a round shape, among other examples, depending on a need in a given application. In some implementations, the mode filter structure 126 can be formed using photolithography technique, deep UV lithography, or nano-imprint lithography, among other examples.

In some implementations, the mode filter structure 126 can be formed by etching of the second cap layer 116. The mode filter structure 126 (e.g., the top step of the stepped structure) may have a second etch depth 128 and/or a size 130 (e.g., a width, a diameter, or another measurement of size in a given direction). Accordingly, such as due to the second etch depth 128 of the mode filter structure 126 and/or the size 130 of the mode filter structure 126, the mode filter structure 126 may be configured to reduce a quantity of optical modes (e.g., a quantity of spatial optical modes) supported by the mode filter structure 126 (and therefore supported by the VCSEL 102).

Accordingly, the mode filter structure 126 (e.g., due to the second etch depth 128 of the mode filter structure 126 and/or the size 130 of the mode filter structure 126) may be configured to support a single optical mode (e.g., a single spatial optical mode). This may cause the VCSEL 102 to be a single-mode (SM) VCSEL (e.g., that emits a laser beam with only one optical mode, such as a fundamental optical mode). Alternatively, the mode filter structure 126 (e.g., due to the second etch depth 128 of the mode filter structure 126 and/or the size 130 of the mode filter structure 126) may be configured to support one or more optical modes (e.g., by allowing lasing of the one or more optical modes and/or by suppressing lasing of one or more other optical modes). This may cause the VCSEL 102 to be a reduced-mode (RM) VCSEL (e.g., that emits a laser beam with a reduced number of optical modes, such as a fundamental optical mode and one or more higher order optical modes).

Notably, the mode filter structure 126 can be used for any shape of confinement aperture 108, such as a circular confinement aperture 108 or an asymmetric confinement aperture 108. Further, a shape of the mode filter structure 126 may in some implementations match a shape of the confinement aperture 108. In some implementations, the size 130 of the mode filter structure 126 may have be the same as, or similar to, the size 120 of the confinement aperture 108. Alternatively, an overlap (within a tolerance), a slightly larger or a slightly smaller mode filter structure 126 than confinement aperture 108 may be used.

The protective layer 118 may include a layer that acts as a protective passivation layer and/or a reflective layer. For example, protective layer 118 may include one or more sub-layers (e.g., a dielectric passivation layer and/or a mirror layer, an SiO₂ layer, an Si₃N₄ layer, an Al₂O₃ layer, or other layers) deposited (e.g., by chemical vapor deposition, atomic layer deposition, or other techniques) on one or more other layers of the VCSEL 102.

As shown in FIGS. 1A-1B, the first cap layer 112 and the second cap layer 116 may be disposed (e.g., in a stack) over the confinement aperture 108. Accordingly, the polarization filter structure 122 (e.g., that is formed in the first cap layer 112) and the mode filter structure 126 (e.g., that is formed in the second cap layer 116) may be disposed (e.g., in a stack) over the confinement aperture 108. In some implementations, as shown in FIG. 1A, the first cap layer 112 may be between the confinement aperture 108 and the second cap layer 116, and thus the polarization filter structure 122 may be disposed between the confinement aperture 108 and the mode filter structure 126. Alternatively, as shown in FIG. 1B, the second cap layer 116 may be between the confinement aperture 108 and the first cap layer 112, and thus the mode filter structure 126 may be disposed between the confinement aperture 108 and the polarization filter structure 122. Accordingly, in either case, as further shown in FIGS. 1A-1B, a first distance between the confinement aperture 108 and the etch stop layer 114 (e.g., that is disposed over the confinement aperture 108) may be less than at least one of a second distance between the confinement aperture 108 and the first cap layer 112 (and between the confinement aperture 108 and the polarization filter structure 122) and a third distance between the confinement aperture 108 and the second cap layer 116 (and between the confinement aperture 108 and the mode filter structure 126).

In some implementations, the first etch depth 124 of the polarization filter structure 122 and the second etch depth 128 of the mode filter structure 126 may be different (e.g., from each other). For example, the first etch depth 124, as determined by designed, may cause the polarization filter structure 122 to suppress orthogonal polarization orientations of light and to therefore support only a single polarization orientation. This may then cause the VCSEL 102 to support a single polarization orientation. As another example, the second etch depth 128, as determined by designed, may cause the mode filter structure 126 to reduce a quantity of optical modes supported by the mode filter structure 126 (and therefore supported by the VCSEL 102). This may cause the VCSEL 102 to be an SM VCSEL or an RM VCSEL.

In some implementations, characteristics of the polarization filter structure 122 (e.g., the first etch depth 124 of the polarization filter structure, the pitch of the gratings of the polarization filter structure 122, the pattern of the gratings of the polarization filter structure 122, the shape of the polarization filter structure 122, a direction of grooves of the polarization filter structure 122, and/or a size of the polarization filter structure 122) and characteristics of the mode filter structure 126 (e.g., the second etch depth 128 of the mode filter structure 126, the size 130 of the mode filter structure 126, and/or the shape of the mode filter structure 126,) are independently determined (or independently selected) to provide an optimal performance of the polarization filter structure 122 and the mode filter structure 126, respectively. That is, the characteristics of the polarization filter structure 122 (e.g., the first etch depth 124 and/or other characteristics) may be designed to provide an optimal configuration of the polarization filter structure 122 (e.g., to support a single polarization orientation for a laser beam emitted by the VCSEL 102). And, the characteristics of the mode filter structure 126 (e.g., the second etch depth 128, the size 130, and/or other characteristics) may be designed to provide an optimal configuration of the mode filter structure 126 (e.g., to support a reduced number of optical modes, such a single optical mode). In this way, some implementations described herein enable independent control of a polarization orientation (e.g., via the configuration of the polarization filter structure 122) and an optical mode (e.g., via the configuration of the mode filter structure 126) of the VCSEL 102. Thus, in some cases, corresponding characteristics of the polarization filter structure 122 and the mode filter structure 126 and (e.g., the first etch depth 124 and the second etch depth 128) may be different, or, in other cases, may be the same.

The number, arrangement, thicknesses, order, symmetry, or the like, of layers shown in FIGS. 1A-1B are provided as an example. In practice, the VCSEL 102 may include additional layers, fewer layers, different layers, differently constructed layers, or differently arranged layers than those shown in FIGS. 1A-1B. For example, as noted above, the VCSEL 102 may in some implementations be a bottom-emitting VCSEL, and a structure similar to that shown in FIGS. 1A-1B may utilized for bottom emission, with appropriate modification to support bottom emission (e.g., an output aperture can be formed at a bottom of the VCSEL rather than a top of the VCSEL). Additionally, or alternatively, a set of layers (e.g., one or more layers) of the VCSEL 102 may perform one or more functions described as being performed by another set of layers of the VCSEL 102, and any layer may include more than one layer. While some implementations described herein are directed to a single VCSEL (e.g., VCSEL 102), some implementations include multiple VCSELs (e.g., multiple VCSELs 102).

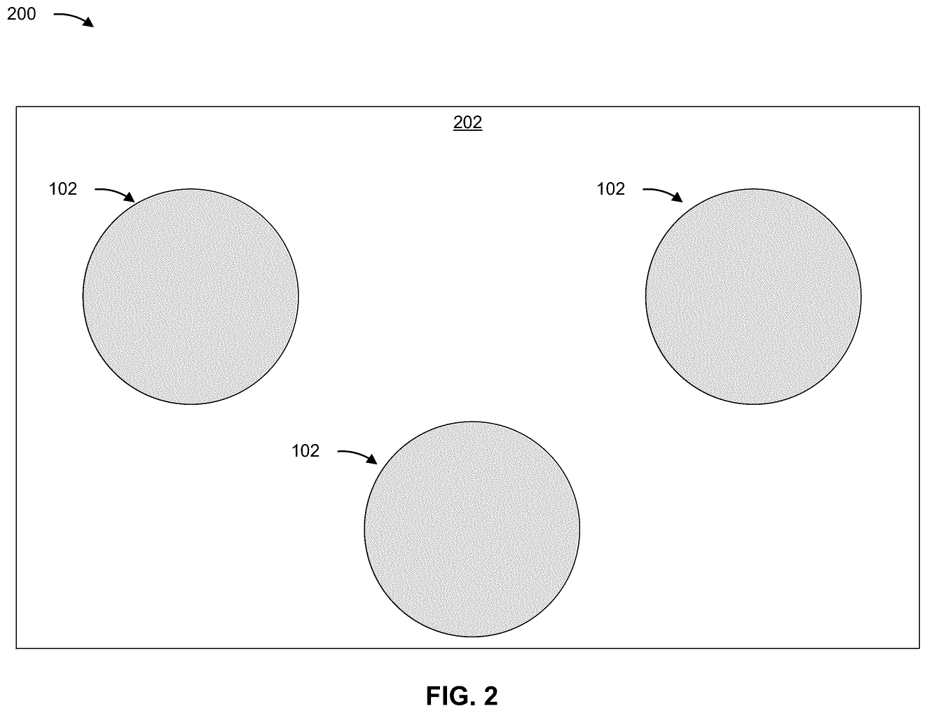

FIG. 2 is diagram associated with an example optical device 200. The example optical device 200 may be, for example, an optical communication device, an optical sensing device, an optical interconnection device, an optical structured light device, or another type of optical device. The optical device 200 may include an optical assembly 202, which may include one or more VCSELs 102 (shown in FIG. 2 as three VCSELs 102), which may be arranged in a pattern (e.g., a one dimensional array, a two-dimensional array, or another type of pattern) within the optical assembly 202.

The one or more VCSELs 102 may be configured to emit respective laser beams, such as respective laser beams that are to couple into (e.g., enter into) an input end of an optical fiber (e.g., a single mode or a multi-mode fiber). Alternatively, the one or more VCSELs may couple to an optical component or optical system (for example, a lens or a system of lenses). The respective laser beams may be associated with a same spectral range. That is, each VCSEL 102 may be configured to emit a laser beam associated with a particular spectral range. For example, each VCSELs 102 may be configured to emit a laser beam associated with a spectral range that has an 850 nm center wavelength.

Further, each VCSEL 102 may be configured to emit a laser beam that has one or more optical modes and a single polarization orientation. For example, each VCSEL 102 may include a polarization filter structure 122 (e.g., formed in a first cap layer 112) that supports a single polarization orientation and a mode filter structure 126 (e.g., formed in a second cap layer 116) that supports one or more optical modes. The polarization filter structure 122 and the mode filter structure 126 may be formed in different layers, and therefore may be independent of each other. Accordingly, the polarization filter structure 122 and the mode filter structure 126 may each be optimally configured, which facilitates independent control of the polarization orientation and optical mode(s) of the VCSEL 102.

As indicated above, FIG. 2 is provided as an example. Other examples may differ from what is described with regard to FIG. 2.

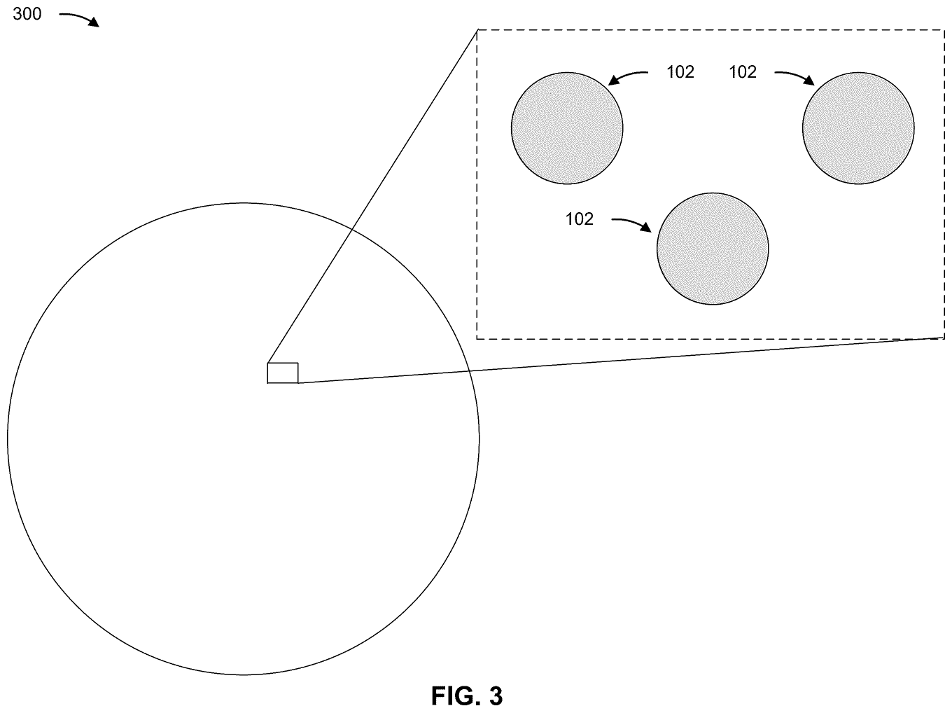

FIG. 3 is diagram associated with an example wafer 300. The wafer 300 may be used to produce integrated circuits, chips, semiconductor lasers, and/or the like. For example, the wafer 300 may be used to form a plurality of VCSELs 102 (e.g., where the plurality of VCSELs 102 are formed on a uniform substrate and then a singulation process can be used to individualize the VCSELs 102 or to form an array of VCSELs 102).

As shown in FIG. 3, the plurality of VCSELs 102 may be formed on a surface (e.g., a top surface) of the wafer 300. As described elsewhere herein, each VCSEL 102 may be configured to emit a laser beam that has one or more optical modes and a single polarization orientation. For example, each VCSEL 102 may include a polarization filter structure 122 (e.g., formed in a first cap layer 112) that supports a single polarization orientation and a mode filter structure 126 (e.g., formed in a second cap layer 116) that supports one or more optical modes. The polarization filter structure 122 and the mode filter structure 126 may be formed in different layers, and therefore may be independent of each other. Accordingly, the polarization filter structure 122 and the mode filter structure 126 may each be optimally configured, which facilitates independent control of the polarization orientation and optical mode(s) of the VCSEL 102.

As indicated above, FIG. 3 is provided as an example. Other examples may differ from what is described with regard to FIG. 3.

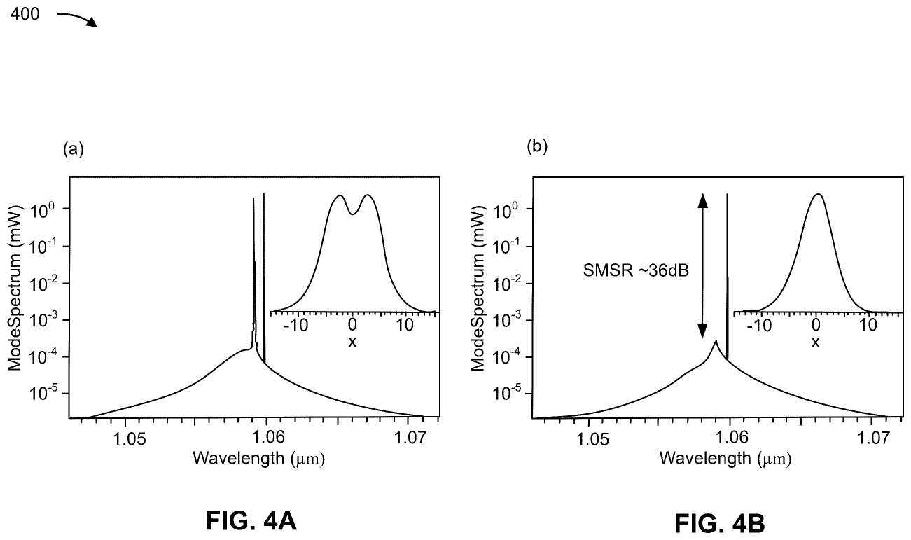

FIGS. 4A-4B show single mode operation of similarly configured VCSELs at high bias currents. FIG. 4A shows an optical spectrum of a VCSEL (e.g., with a 5.5 μm confinement aperture, operating at 8 milliamps (mA)) that does not include any mode filter structure. Here, two modes (e.g., two almost equal modes) of a laser beam emitted by the VCSEL compete. Accordingly, as shown in the inset in FIG. 4A, in a one-dimensional (1D) far-field cross-section, a beam profile of the laser beam has distinct humps and does not resemble a Gaussian-type beam profile.

FIG. 4B shows an optical spectrum of the VCSEL 102 described herein (e.g., with a 5.5 μm confinement aperture 108, operating at 8 mA) that includes the second cap layer 116 and the mode filter structure 126 (e.g., with a size 130 of 6.0 μm). Here, single mode operation of the VCSEL 102 is demonstrated with a side mode suppression ratio (SMSR) at, or approximately at, 36 decibels (dB). Accordingly, as shown in the inset in FIG. 4B, in a 1D far-field cross-section, a beam profile of a laser beam emitted by the VCSEL 102 resembles a Gaussian-type beam profile.

As indicated above, FIGS. 4A-4B are provided as an example. Other examples may differ from what is described with regard to FIGS. 4A-4B.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical-cavity surface-emitting laser (VCSEL), comprising:
a first cap layer including a semiconductor material disposed over a confinement aperture of the VCSEL; and
a second cap layer including a dielectric material disposed over the confinement aperture of the VCSEL, wherein:
a polarization filter structure is formed in the first cap layer, and
a mode filter structure is formed in the second cap layer.

2. The VCSEL of claim 1, wherein the polarization filter structure includes a grating structure.

3. The VCSEL of claim 1, wherein the mode filter structure includes a stepped structure.

4. The VCSEL of claim 1, wherein:
the polarization filter structure is associated with a first etch depth;
the mode filter structure is associated with a second etch depth; and
the first etch depth and the second etch depth are different.

5. The VCSEL of claim 1, wherein:
the first cap layer and the second cap layer are disposed in a stack over the confinement aperture of the VCSEL; and
the first cap layer is between the confinement aperture and the second cap layer.

6. The VCSEL of claim 1, wherein:
the first cap layer and the second cap layer are disposed in a stack over the confinement aperture of the VCSEL; and
the second cap layer is between the confinement aperture and the first cap layer.

7. The VCSEL of claim 1, wherein the VCSEL further comprises an etch stop layer, wherein:
the etch stop layer is disposed over the confinement aperture; and
a first distance between the confinement aperture and the etch stop layer is less than at least one of a second distance between the confinement aperture and the first cap layer or a third distance between the confinement aperture and the second cap layer.

8. The VCSEL of claim 1, wherein the VCSEL supports a single spatial optical mode and a single polarization orientation.

9. An optical assembly, comprising:
a plurality of vertical-cavity surface-emitting lasers (VCSELs), wherein each VCSEL comprises:
a first cap layer; and
a second cap layer, wherein:
a polarization filter structure is formed in the first cap layer, and
a mode filter structure is formed in the second cap layer.

10. The optical assembly of claim 9, wherein the polarization filter structure includes a grating structure.

11. The optical assembly of claim 9, wherein the mode filter structure includes a stepped structure.

12. The optical assembly of claim 9, wherein:
the polarization filter structure is associated with a first etch depth;
the mode filter structure is associated with a second etch depth; and
the first etch depth and the second etch depth are different.

13. The optical assembly of claim 9, wherein:
the first cap layer and the second cap layer are disposed in a stack over a confinement aperture of the VCSEL; and
the first cap layer is between the confinement aperture and the second cap layer.

14. The optical assembly of claim 9, wherein:
the first cap layer and the second cap layer are disposed in a stack over a confinement aperture of the VCSEL; and
the second cap layer is between the confinement aperture and the first cap layer.

15. The optical assembly of claim 9, wherein each VCSEL further comprises an etch stop layer, wherein:
a first distance between a confinement aperture of the VCSEL and the etch stop layer is less than at least one of a second distance between the confinement aperture and the first cap layer or a third distance between the confinement aperture and the second cap layer.

16. A wafer, comprising:
a plurality of vertical-cavity surface-emitting lasers (VCSELs), wherein each VCSEL comprises:
a polarization filter structure disposed over a confinement aperture of the VCSEL; and
a mode filter structure disposed over the confinement aperture of the VCSEL.

17. The wafer of claim 16, wherein the polarization filter structure includes a grating structure.

18. The wafer of claim 16, wherein the mode filter structure includes a stepped structure.

19. The wafer of claim 16, wherein:
the polarization filter structure is associated with a first etch depth;
the mode filter structure is associated with a second etch depth; and
the first etch depth and the second etch depth are different.

20. The wafer of claim 16, wherein each VCSEL further comprises an etch stop layer, wherein:
the etch stop layer is disposed over the confinement aperture; and
a first distance between the confinement aperture and the etch stop layer is less than at least one of a second distance between the confinement aperture and the polarization filter structure or a third distance between the confinement aperture and the mode filter structure.
